(19) United States
(12) Patent Application Publication
(10) Pub. No.: US 2006/0158269 A1
(43) Pub. Date: Jul. 20, 2006

(54) Electronic circuit including at least one first differential pair with the transistors sharing one and the same source or one and the same drain

(75) Inventors: Stanislas Gibet, Carquefou (FR); Abdellatif Bendraoui, Saint-Julien de Concelles (FR); Gilles Mercier, Carquefou (FR)

Correspondence Address: WESTMAN CHAMPLIN & KELLY, P.A., SUITE 1400, 900 SECOND AVENUE SOUTH, MINNEAPOLIS, MN, 55402-3319, US

(73) Assignee: Atmel Nantes SA, Nantes Cedex (FR)

(21) Appl. No.: 11/311,693

(22) Filed: Dec. 19, 2005

(30) Foreign Application Priority Data
Dec. 20, 2004 (FR) 04/13606

(51) Int. Cl. H03K 3/03

(52) U.S. Cl. 331/57

(57) ABSTRACT

The disclosure relates to an electronic circuit including at least one first differential pair including first and second transistors. The first and second transistors share one and the same single source or one and the same single drain.

### FIELD OF THE DISCLOSURE

The field of the disclosure is that of electronic integrated circuits and more particularly that of integrated-circuit design.

To be more precise, the disclosure relates to the optimisation of the topology of integrated circuits, and particularly the optimisation of the topology of voltage-controlled oscillators (known as VCO).

### BACKGROUND OF THE DISCLOSURE

The function of a voltage-controlled oscillator is to generate a periodic output signal, the frequency of which is a function of a continuous voltage applied to an input. It thus allows periodic signals to be generated, the frequency of which is open to selection.

There are several types of voltage-controlled oscillator. A first example of a VCO is the VCO of the RC type, which is based on loading and unloading a capacitance through a capacitor.

A second example of a VCO is the voltage-controlled differential oscillator, designated hereinafter as a differential VCO. The differential VCO conventionally includes four transistor based differential pairs.

FIG. 1 shows a simplified diagram of a conventional differential VCO 10. The differential VCO includes first 11, second 12, third 13 and fourth 14 amplifying stages. Amplifying stages 11 to 14 are polarised by means of a bias voltage VBIAS applied to an input 15 of the differential VCO 10. Each stage includes two inputs, 111 and 112, 121 and 122, 131 and 132, 141 and 142 respectively, and an output 113, 123, 133 and 143 respectively.

The output 133 of the third stage supplies the periodic output voltage of the differential VCO 10 the frequency of which depends on the bias voltage VBIAS.

FIG. 2A shows the diagram of a conventional amplifying stage of the differential VCO 10, for example the first stage 11. For example, all the stages 11 to 14 of the differential VCO 10 are identical.

This first stage 11 conventionally includes:
a conventional differential pair 114 based on two P-type MOS transistors M1, M2;
a current source 115 including one P-type MOS transistor M3; and
an active load 116 based on two N-type MOS transistors M4, M5.

The inputs 111, 112 of the first stage 11 are connected to the gates of the transistors M1, M2 of the differential pair 114. The output 113 of the first stage 11 is connected to the drain of the transistor M2 of the differential pair 114.

The sources of the transistors M1, M2 of the differential pair 114 are connected to one and the same common node N.

A known technique (shown in FIG. 2B) for increasing the power supply rejection of an amplifying stage 21 is to connect the NWELL of the transistors 201, 202 of the differential pair 214 to a common node N.

When designing a differential pair that includes two transistors M1 and M2, each of the transistors of the pair, for example the transistor M1, can conventionally be replaced by two transistors M11, M12 each having a gate width two times smaller and a gate length identical to that of the transistor M1.

FIG. 3 shows the diagram of a differential pair 314 of this kind in which each of the transistors has been split so as to form two pairs of transistors M11 and M12, M22 and M21 respectively. FIG. 4 is a diagram of the topology of the transistors M11, M12, M22 and M21 of the differential pair 314 in FIG. 3 in the case of a “crossed pair” arrangement. A number of metal strips (not shown in FIG. 4) allow the electrical connections in FIG. 3 to be made between the different contacts of the transistors.

It may be noted that in this FIG. 4 but also in those that follow, the areas marked by black dots are doped zones in which the transistors are made.

The four transistors of the differential pair 314 are equivalent to two transistors forming the pair 314. The “crossed pair” arrangement makes it possible to ensure a good uniformity of dimensions of these two equivalent transistors when the pair is manufactured.

Indeed, any variation in dimension due to the manufacturing process, and any interference that causes parasitic effects in the transistors (noise, temperature variation, etc) is transmitted in the same way to each of these two equivalent transistors.

In fact, a lack of uniformity in respect of the dimensions of the transistors of a differential pair (for example the pair 314 in FIG. 3) generates an offset voltage between the two inputs of the pair (311 and 312) that may well interfere with the operation of an amplifying stage that includes the pair.

Specialists in the manufacture of transistors therefore consider that it is necessary to employ the “crossed pairs” arrangement when manufacturing a differential pair.

However, this arrangement generates parasitic capacitances (capacitances due to the metal strips connecting the transistors, diffusion capacitance of the transistors, bottom or sidewall capacitance between the wells of the transistors and the substrate, etc) that restrict the performance of the differential VCO, in particular by reducing its oscillation frequency.

VCOs are able to operate in different frequency ranges and to be made according to different technologies, each associated with a pitch that is generally indicated in microns.

The growing need to reduce power consumption and the dimensions of electronic systems based on integrated circuits has led designers of VCOs of this kind to use manufacturing technologies that have an increasingly small pitch.

In this way, for example in order to make a phase locked loop (or PLL) for a USB port according to the USB 2.0 standard, it may be necessary to make VCOs by means of technologies that have a pitch below 0.5 μm and which operate at a frequency of about 480 MHz (for an internal clock of 12 MHz).

Generally speaking, VCOs operating at high frequencies (above 300 MHz) and made from very small-scale technologies (below 0.5 μm) are VCOs of the RC type. Indeed, the man skilled in the art considers that, should it be required to make a differential VCO operating at these frequencies from a technology below 0.5 μm, the transistors of the differential pairs of this differential VCO would be too small to ensure good uniformity in the dimensions of the transistors of the VCO despite the use of the “crossed pairs” arrangement.

### SUMMARY

An embodiment of the present invention is directed to an electronic circuit that includes at least one first differential pair including first and second transistors. The first and second transistors share one and the same source or one and the same drain.

In this way, an embodiment of the invention sets out to counter the prejudices of the person skilled in the art by proposing an electronic circuit based on differential pairs with the transistors of the differential pairs not being arranged as a “crossed pair” and therefore able not to be of uniform dimensions.

A general principle of an embodiment of the invention is based on the implementation of a differential pair that includes a double transistor obtained by means of two transistors that share one and the same source or one and the same drain.

Thus, the implementation of double transistors of this kind makes it possible to obtain circuits based on differential pairs that have parasitic capacitances and an occupied semiconductor surface that are clearly smaller compared with conventional circuits.

According to a first advantageous embodiment of the invention, said first and second transistors are P-type MOS transistors and they share one and the same single drain.

According to a second advantageous embodiment of the invention, said first and second transistors are N-type MOS transistors and in that they share one and the same single source.

To advantage, the electronic circuit additionally includes at least one second differential pair (62, 72), all the transistors of said first and at least one second differential pairs being included in a single well (76).

In this way, the use of a single well makes it possible to reduce the influence of the parasitic bottom and sidewall capacitances.

In one or more embodiments, the electronic circuit includes four amplifying stages each including at least one of said differential pairs, all the transistors of said differential pairs being included in a single well.

According to one advantageous embodiment of the invention, the electronic circuit is manufactured by means of a technology with a pitch below 0.5 μm.

In one embodiment, the electronic circuit is a differential voltage-controlled oscillator.

For example, the electronic circuit is designed to operate at a frequency above 300 MHz.

In this way, an embodiment proposes a differential VCO operating at frequencies above 300 MHz and made by means of a technology below 0.5 μm. Other characteristics of one or more embodiments of the invention will emerge more clearly from reading the following description of a preferential embodiment, given as a simple illustrative and non-restrictive example, and the appended drawings.

### BRIEF DESCRIPTION OF THE DRAWINGS

FIG. 1 shows a simplified diagram of a conventional differential VCO based on four amplifying stages;

FIGS. 2A and 2B show two diagrams of a conventional amplifying stage based on a differential pair of the differential VCO in FIG. 1;

FIG. 3 shows the diagram of a conventional differential pair made from four transistors;

FIG. 4 is a diagram of the topology of the transistors of the differential pair in FIG. 3 in the case of a “crossed pair” arrangement;

FIG. 5 is a diagram of the topology of the transistors of a conventional differential VCO including four differential pairs arranged as “crossed pairs”;

FIG. 6 is a diagram of the topology of the transistors of a differential VCO according to a first embodiment of the invention;

FIG. 7 is a diagram of the topology of the transistors of a differential VCO according to a second embodiment of the invention.

### DETAILED DESCRIPTION OF THE ILLUSTRATIVE EMBODIMENTS

The topology of a conventional differential VCO 50 is shown, in relation to FIG. 5, with the transistors arranged as “crossed pairs”.

This VCO 50 includes sixteen P-type MOS transistors 501 to 516, forming first 501, 505, 509, 513, second 502, 506, 510, 514, third 503, 507, 511, 515 and fourth 504, 508, 512, 516 transistors of four differential pairs 51 to 54 (the other components of the VCO 50 are not shown in this FIG. 5).

The four transistors of each of the differential pairs 51 to 54 are manufactured in one and the same well, 571, 572, 573, 574 respectively.

For example, the first transistor 501 of the differential pair 51 of the VCO 50 has a source 5011, a drain 5012 and a gate 5013.

The four differential pairs 51 to 54 occupy a significant semiconductor surface. For example, for transistors 501 to 516 that have a gate width (denoted w5) substantially equal to 5 μm, a total surface occupied by the four differential pairs is obtained that is substantially equal to 280 μm².

A conventional transistor arrangement of this kind for implementing a differential VCO requires the employment of a high number of metal strips in order to establish the electrical connections of the contacts of the transistors needed for the VCO to operate.

In this way, a topology of this kind generates, through the high number of metal strips required, significant parasitic capacitances.

We will consider hereinafter the implementation of differential VCOs through the use of technologies with a pitch below 0.5 μm, and which operate at frequencies above 300 MHz.

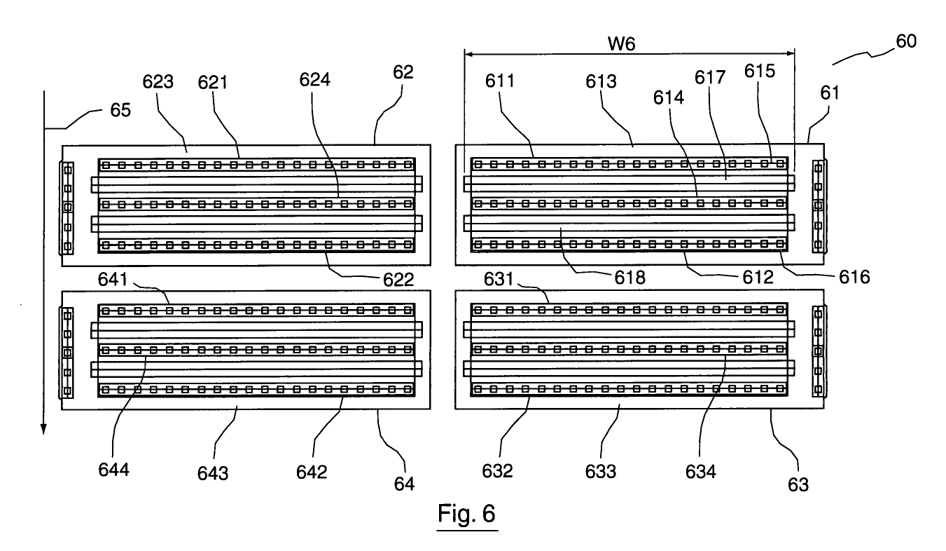

A diagram is shown in relation to FIG. 6 of the topology of the transistors of a differential VCO 60 according to a first embodiment of the invention.

This VCO 60 includes eight P-type MOS transistors 611, 621, 631, 641, 612, 622, 632, 642, forming first 611, 621, 631, 641, and second 612, 622, 632, 642 transistors of four differential pairs 61 to 64 (the other components of the VCO 60 are not shown in this FIG. 6).

The two transistors of each of the differential pairs 61 to 64 are manufactured in one and the same well, 613, 623, 633, 643 respectively.

The first 611 and second 612 transistors of the differential pair 61 of the VCO 60 each has a source 615, 616 respectively and a gate 617, 618 respectively.

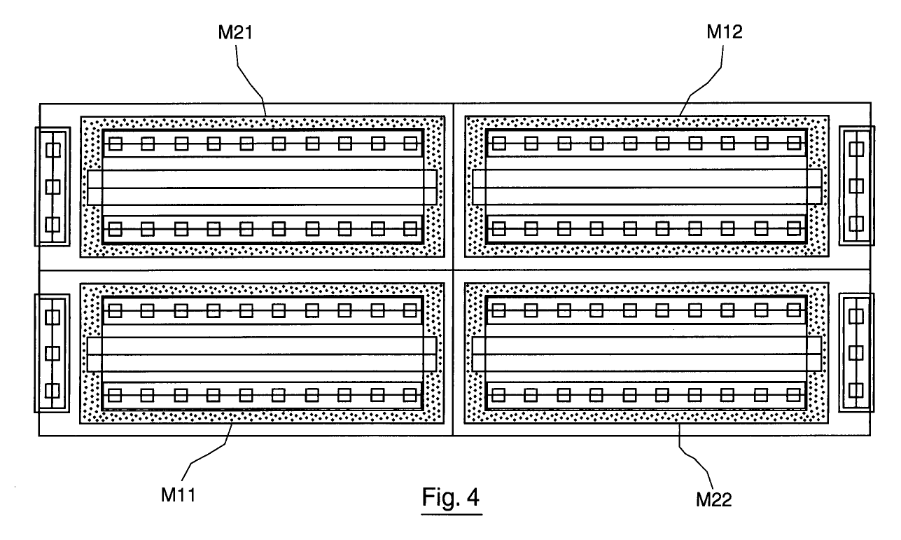

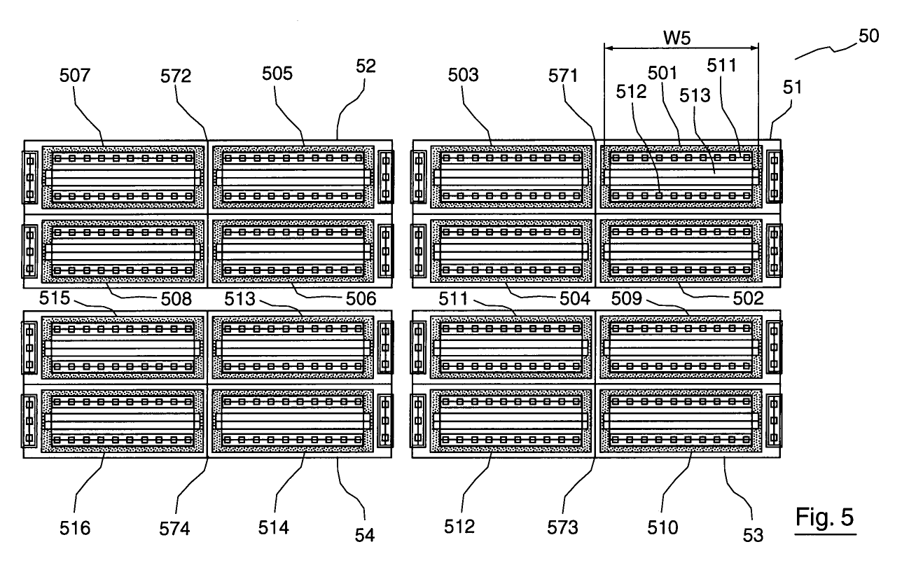

In the interests of simplification, we have not shown in this FIG. 6 the doped zones (surrounding the transistors) previously introduced in relation to FIG. 4.

Unlike the differential VCO 50 in FIG. 5, in which each of the differential pairs, arranged as crossed pairs, includes four transistors, each differential pair 61 to 64 of the differential VCO 60 according to an embodiment of the invention includes only one first 611, 621, 631, 641 and one second 612, 622, 632, 642 transistors. These transistors however have a gate width w6 approximately two times larger (for example w6=10 μm) than those of the transistors of the differential VCO 50.

On the other hand, in each differential pair 61 to 64 of the differential VCO 60, the first 611, 621, 631, 641 and second 612, 622, 632, 642 transistors share one and the same single drain 614, 624, 634, 644 respectively.

In this way, the four differential pairs 61 to 64 of the topology in FIG. 6 occupy a smaller semiconductor surface than the four differential pairs arranged according to the conventional “crossed pairs” topology in FIG. 5.

Indeed, on the one hand, in each differential pair 61 to 64, in order to share a common drain 614, 624, 634, 644, the first and second transistors are brought closer together in a horizontal direction 65 compared with the conventional “crossed pairs” topology in FIG. 5.

And on the other hand, in the differential VCO 60, according to an embodiment of the invention, each of the transistors of each of the differential pairs, for example the first transistor 611 of the pair 61, is equivalent to two transistors of a differential pair, for example the first and third transistors 501, 503 of the pair 51, of the conventional VCO in FIG. 5.

In this way, despite the fact that the transistors of the differential VCO 60 according to an embodiment of the invention have a dual surface compared with those of the “crossed pairs” topology, a saving of inter-transistor surface is achieved in the differential VCO 60 according to an embodiment of the invention.

For example, for first 611, 621, 631, 641 and second 612, 622, 632, 642 transistors that have a gate width substantially equal to 10 μm, a total surface occupied by the four differential pairs is obtained that is substantially equal to 185 μm², whereas we have a surface of 280 μm² in the case of the “crossed pairs” topology in FIG. 6.

Furthermore, compared with the conventional “crossed pairs” topology, this topology according to the first embodiment of the invention makes it possible to reduce the number (given the common drains and reduced number of transistors) and the length (given the fact that the transistors have been brought closer together) of the metal strips needed to establish the electrical connections of the differential VCO 60, and therefore the parasitic capacitances related to these electrical strips.

For example, according to the conventional “crossed pairs” topology (FIG. 5), it is necessary to make the connections between the first 501, 505, 509, 513 and fourth 504, 508, 512, 516 transistors and between the second 502, 506, 510, 514 and third 503, 507, 511, 515 transistors. In fact, these connections give rise, for each differential pair 51 to 54, to four intersecting metal strips, in other words four intersecting parasitic capacitances of about 1.5 fF each.

In the topology according to the first embodiment of the invention, these connections have no cause to be there, which gives freedom from sixteen intersecting parasitic capacitances of 1.5 fF each compared with the “crossed pairs” topology.

In the next place, this topology according to the first embodiment of the invention makes it possible to reduce the influence of the parasitic diffusion capacitances of the transistors of the differential VCO 60 compared with the parasitic diffusion capacitances of the transistors of the differential VCO 50.

Indeed the diffusion capacitance Cdiff1 seen by a source, for the pair of transistors 501 and 503 according to the conventional “crossed pairs” topology in FIG. 5, may be written:
Cdiff1=2Cja.a.b+2Cjb.(2a+2b)=2Cja.a.b+Cjb.(4a+4b)

where a is the source length of the transistors 501 and 503, b is the source width of the transistors 501 and 503, Cja is the junction capacitance per unit area (expressed as F/m²), Cjb is the sidewall capacitance per unit length (expressed as F/m).

In the case of the first transistor 611 (the source length of which is substantially equal to 2a and the source width is substantially equal to b) according to the topology of the first embodiment of the invention, the diffusion capacitance CdiffDC2 seen by a source, may be written:
Cdiff2=2Cja.a.b+Cjb.(4a+2b)=2Cja.a.b+Cjb.(4a+2b)

For example, Cja=1.28.10⁻³ F/m² and Cjb=3.28.10⁻¹⁰ F/m.

In a first example of a transistor that has a relatively significant source length: a=16 μm and b 0.47 μm, we obtain Cdiff1=40.85 fF and Cdiff2=40.55 fF.

In a second example of a transistor that has a relatively small source length: a=1 μm and b=0.47 μm, we get Cdiff=3.1 fF and Cdiff2=2.8 fF.

As a consequence, in the case of small size transistors, like the one in the aforementioned second example, the topology according to the second embodiment of the invention makes it possible to reduce the diffusion capacitance by 10% compared with the “crossed pairs” topology.

Given that the transistors of the differential VCO in FIG. 6 are not arranged as “crossed pairs” and that they are of small dimensions (for example, of the order of 2 μm for the length of the source and drain diffusion zones and 0.47 μm for their width), these transistors are not generally of uniform dimensions.

This lack of uniformity in respect of the dimensions of the transistors 611, 621, 631, 641, 612, 622, 632, 642 of the differential pairs 61 to 64 generates an offset between the two inputs of each of the pairs 61 to 64.

However, contrary to the opinion of the man skilled in the art, these offsets do not harm the operation of the differential VCO 60, on the contrary, these offsets are an advantage when starting the oscillator.

Generally speaking, differential VCOs use the noise of their power supply for their start-up (the noise is broadband and therefore includes a component that has the right frequency, which is amplified and which initiates the oscillation).

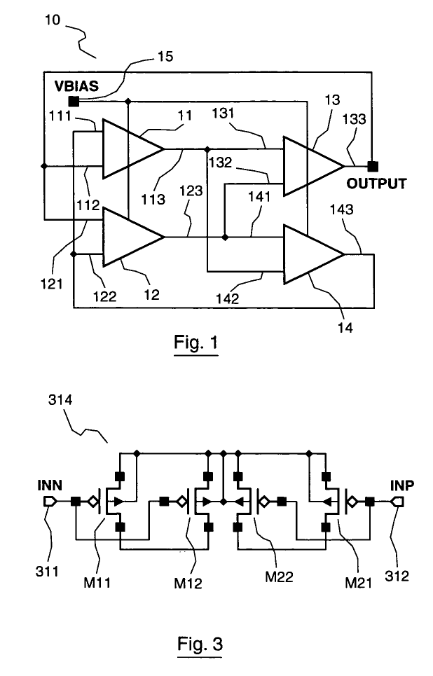

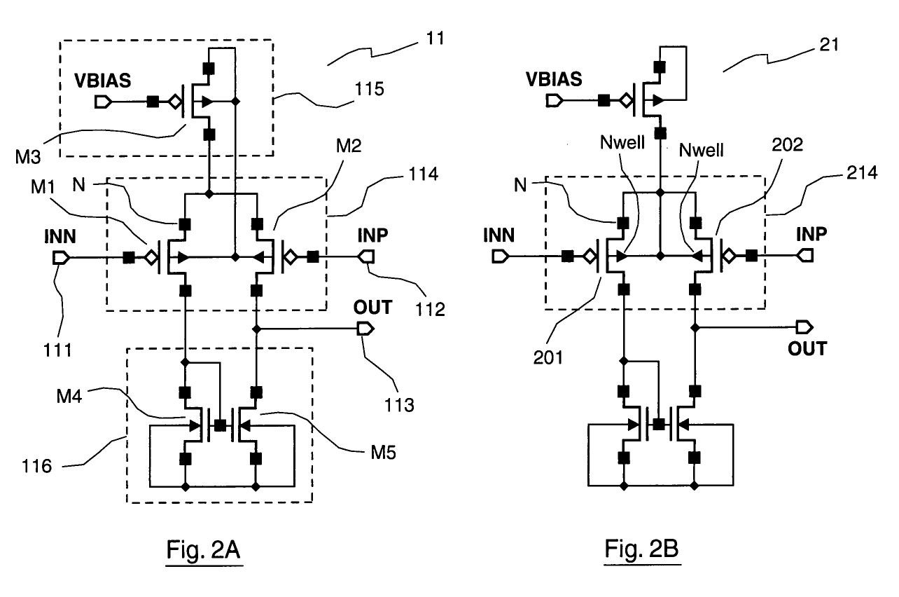

However this start-up process is uncertain and takes time. Indeed, each amplifying stage of the differential VCO 10 in FIG. 1 reacts like a comparator, it is the voltage difference applied to its two differential inputs that allows an output voltage to be generated. In the assembly in FIG. 1, the four amplifying stages 11 to 14 generate instability in the operation of the VCO 10 and therefore an oscillation.

However, there is a risk that each of the inputs of the differential amplifiers may be at the same potential despite the presence of the power supply noise, which corresponds to a VCO rest point and therefore an absence of oscillation. The offsets between the inputs of each of the pairs 61 to 64 allow freedom from this rest point.

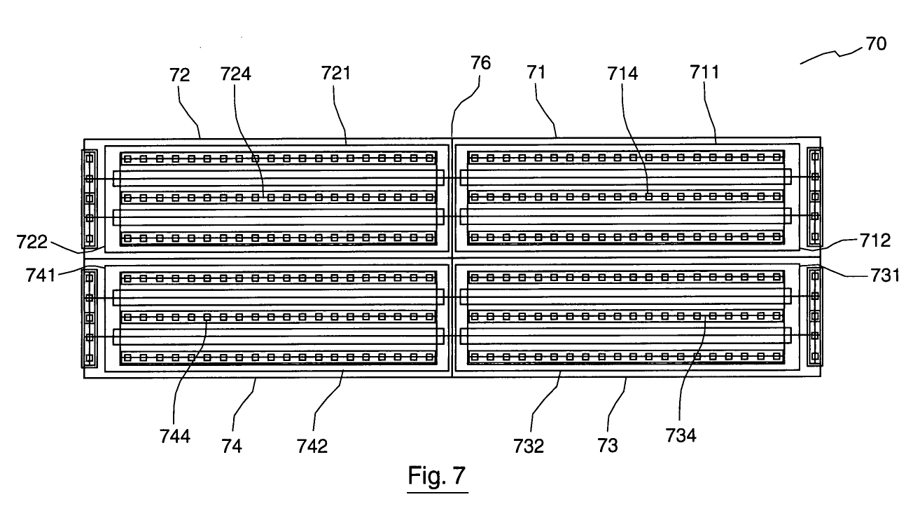

A diagram is shown in relation to FIG. 7 of the topology of the transistors of a differential VCO 70 according to a second embodiment of the invention.

This VCO 70 includes eight P-type MOS transistors forming first 711, 721, 731, 741 and second 712, 722, 732, 742 transistors of four differential pairs 71 to 74 (the other components of the VCO 70 are not shown in this FIG. 7).

In the same way as the topology according to the first embodiment of the invention (FIG. 6), in each differential pair 71 to 74 of the VCO 70, the first 711, 721, 731, 741 and second 712, 722, 732, 742 transistors share one and the same single drain 714, 724, 734, 744 respectively.

Unlike the topology according to the first embodiment of the invention (FIG. 6), in the topology according to this second embodiment, the four differential pairs 71 to 74 are manufactured in one and the same single well 76.

In this way this topology according to the second embodiment of the invention makes it possible to reduce the parasitic capacitances related to the electrical strips and the diffusion capacitances of the transistors compared with the “crossed pairs” topology according to the prior art, in the same way as the topology according to the first embodiment of the invention (described in relation to FIG. 6).

But this topology according to the second embodiment of the invention additionally makes it possible to reduce the parasitic capacitances between the well and the substrate of the transistors 711, 721, 731, 741, 712, 722, 732, 742. Among these parasitic capacitances, the bottom capacitances can be distinguished from the sidewall capacitances.

Indeed, the bottom CSURF1 and sidewall CPERI1 capacitances, for the four differential pairs 51 to 54 according to the conventional “crossed pairs” topology (implementing one well per differential pair) in FIG. 5, may be written:

CSURF1=4H.L.Cjnwell and

CPERI1=4.2(H+L).Cjswnwell

where H is the height of the wells 571 to 574, L is the length of the wells 571 to 574, Cjjnwell is the drain, source capacitance per unit area/NWELL (expressed as F/m²), Cjswnwell is the drain, source sidewall capacitance/NWELL (expressed as F/m).

For the four differential pairs 71 to 74 according to the topology of the second embodiment of the invention implementing a single well 76 of length 2L and of height 2H, the bottom CSURF2 and sidewall CPERI2 capacitances may be written:

CSURF2=4H.L.Cjnwell and

CPERI2=2 (2H+2L).Cjswnwell

For example, Cjnwell=9.55 10⁻⁵ F/m² and Cjswnwell=3.65 10⁻¹ F/m.

For example, by taking H=3 μm and L=2 μm, we obtain CSURF1=2.29 fF, CPERI1=14.6 fF, CSURF2=2.29 fF and CPERI2=7.3 fF.

As a consequence, the topology according to the second embodiment of the invention makes it possible to reduce the parasitic sidewall capacitance by 50% compared with the “crossed pairs” topology.

A description has been given, in relation to FIGS. 6 and 7, of two differential VCO topologies according to two embodiments of the invention in which only transistors of the PMOS type are employed. It should be noted that the man skilled in the art is also able to employ transistors of the NMOS type in these differential VCOs, and in this case, in each differential pair of these VCOs the first and second transistors share one and the same source and not one at the same drain.

In summary, one or more embodiments of the invention overcome drawbacks of the prior art.

One aspect of an embodiment of the invention provides a differential VCO operating at high frequency and made in a very small-scale technology.

Another aspect of an embodiment of the invention implements a VCO of this kind that is high-performance and that in particular offers a reduction in parasitic capacitances compared with conventional VCOs.

Another aspect of an embodiment of the invention provides a VCO of this kind that requires a reduced number of stages during its manufacture and that occupies a small amount of semiconductor surface.

Yet another aspect of an embodiment of the invention implements a VCO of this kind that is straightforward and inexpensive to manufacture.

Clearly, the invention is not restricted to the embodiment examples mentioned above.

In particular one or more embodiments of the invention also apply to any electronic circuit that includes at least one differential pair.

In particular, a person skilled in the art will be able to bring any variant into the choice of transistor type.

Although the present invention has been described with reference to one or more embodiments, workers skilled in the art will recognize that changes may be made in form and detail without departing from the spirit and scope of the invention.

What is claimed is:

1. An electronic circuit including at least one first differential pair including first and second transistors, wherein said first and second transistors share one and the same single source or one and the same single drain.

2. The electronic circuit according to claim 1, wherein said first and second transistors are P-type MOS transistors and share one and the same single drain.

3. The electronic circuit according to claim 1, wherein said first and second transistors are N-type MOS transistors and share one and the same single source.

4. The electronic circuit according to claim 1, and further comprising at least one second differential pair, all the transistors of said first and said at least one second differential pair being included in a single well.

5. The electronic circuit according to claim 1, and further comprising four amplifying stages each including at least one of said first differential pairs, all the transistors of said first differential pairs being included in a single well.

6. The electronic circuit according to claim 1 to 5, wherein the electronic circuit is manufactured by means of a technology with a pitch below 0.5 μm.

7. The electronic circuit according to claim 1, wherein the electronic circuit is a differential voltage-controlled oscillator.

8. The electronic circuit according to claim 7, wherein the electronic circuit is designed to operate at a frequency above 300 MHz.
